(19) United States
(12) Patent Application Publication
(10) Pub. No.: US 2025/0386676 A1
(43) Pub. Date: Dec. 18, 2025

(54) DISPLAY DEVICE AND ELECTRONIC DEVICE INCLUDING DISPLAY DEVICE

(71) Applicant: Samsung Display Co., LTD., Yongin-si (KR)

(72) Inventors: Byung Han YOO, Yongin-si (KR); Kwang Soo BAE, Yongin-si (KR); Yong Jo KIM, Yongin-si (KR); Tae Kyung AHN, Yongin-si (KR); Dae Young LEE, Yongin-si (KR)

(21) Appl. No.: 19/194,564

(22) Filed: Apr. 30, 2025

(30) Foreign Application Priority Data
Jun. 17, 2024 (KR) 10-2024-0078180
Aug. 7, 2024 (KR) 10-2024-0105647

(51) Int. Cl. H10K 59/122; H10K 39/34

(52) U.S. Cl. CPC H10K 59/122; H10K 39/34

(57) ABSTRACT

A display device includes a display area and a sensing area overlapping at least a portion of the display area. The sensing area includes an emission area, a light-receiving area spaced apart from the emission area, a non-emission area surrounding the emission area and the light-receiving area, and a separator disposed in the non-emission area and positioned adjacent to the light-receiving area.

This application claims priority to Korean Patent Application No. 10-2024-0078180, filed on Jun. 17, 2024, and Korean Patent Application No. 10-2024-0105647, filed on Aug. 7, 2024, and all the benefits accruing therefrom under 35 U.S.C. § 119, the content of which in their entireties are herein incorporated by reference.

### BACKGROUND

### 1. Field

Embodiments of the invention generally relate to a display device and an electronic device including the display device.

### 2. Description of the Related Art

As information technology advances, the importance of display devices, which serve as a medium between users and information, has become more prominent. Accordingly, various types of display device such as liquid crystal display (LCD) devices and organic light emitting display (OLED) devices are widely used in various fields.

### SUMMARY

Embodiments provide a display device, which can prevent lateral leakage, and an electronic device including the display device.

A display device according to an embodiment includes a display area and a sensing area overlapping at least a portion of the display area. In such an embodiment, the sensing area includes a light-emitting area, a light-receiving area spaced from the light-emitting area, a

non-light-emitting area surrounding the light-emitting area and the light-receiving area, and a separator disposed in the non-light-emitting area and adjacent to the light-receiving area.

In an embodiment, in a plan view, the separator may surround the light-receiving area.

In an embodiment, the separator may include a multilayer structure including a first layer and a second layer disposed on the first layer.

In an embodiment, in a cross-sectional view, the first layer may have a tapered shape with a width which gradually decreases in a thickness direction, and the second layer may have a rectangular shape.

In an embodiment, in a cross-sectional view, a width of a bottom surface of the second layer may be wider than a width of a top surface of the first layer.

In an embodiment, the sensing area may further include a hole auxiliary layer overlapping the light-emitting area, the light-receiving area, and the non-light-emitting area, where the hole auxiliary layer is disconnected by the separator, an emitting layer disposed on a portion of the hole auxiliary layer overlapping the light-emitting area, a light-receiving layer disposed on a portion of the hole auxiliary layer overlapping the light-receiving area, an electron auxiliary layer disposed on the hole auxiliary layer, the emitting layer, and the light-receiving layer, where the electron auxiliary layer is disconnected by the separator, and a cathode disposed on the electron auxiliary layer, where the cathode is disconnected by the separator.

A display device according to an embodiment includes a display area and a sensing area overlapping at least a portion of the display area, the sensing area including a light-emitting area, a light-receiving area spaced apart from the light-emitting area, a non-light-emitting area surrounding the light-emitting and light-receiving areas, a first separator positioned adjacent to the light-receiving area, and a second separator positioned adjacent to the light-emitting area.

In an embodiment, in a plan view, the first separator may surround the light-receiving area and the second separator may surround the light-emitting area.

In an embodiment, the first separator may have a multilayer structure including a first layer and a second layer disposed on the first layer, and the second separator may have a same multilayer structure as the first separator.

In an embodiment, in a cross-sectional view, the first layer may have a tapered shape with a width which gradually decreases in a thickness direction, and the second layer may have a rectangular shape.

In an embodiment, in a cross-sectional view, a width of a bottom surface of the second layer may be wider than a width of a top surface of the first layer.

In an embodiment, the sensing area may further include a hole auxiliary layer overlapping with the light-emitting area, the light-receiving area, and the non-light-emitting area, where the hole auxiliary layer is disconnected by the first and second separators, an emitting layer disposed on a portion of the hole auxiliary layer overlapping the light-emitting area, a light-receiving layer disposed on a portion of the hole auxiliary layer overlapping the light-receiving area, an electron auxiliary layer disposed on the hole auxiliary layer, the emitting layer, and the light-receiving layer, where the electron auxiliary layer is disconnected by the first and second separators, and a cathode disposed on the electron auxiliary layer, where the cathode is disconnected by the first and second separators.

A display device according to an embodiment includes a display area and a sensing area which at least partially overlaps the display area, the sensing area including light-emitting areas, which are spaced apart from each other, a light-receiving area spaced apart from the light-emitting areas, a non-light-emitting area surrounding the light-emitting and light-receiving areas, a first separator disposed in the non-light-emitting area adjacent to the light-receiving area, and second separators disposed in the non-light-emitting area and each adjacent to a corresponding one of the light-emitting areas.

In an embodiment, in a plan view, the first separator may surround the light-receiving area and the second separators may each surround the corresponding light-emitting areas.

In an embodiment, the first separator may have a multilayer structure including a first layer and a second layer disposed on the first layer, and the second separators may have a same multilayer structure as the first separator.

In an embodiment, in a cross-sectional view, the first layer may have a tapered shape with a width which gradually decreases in a thickness direction, and the second layer may have a rectangular shape.

In an embodiment, in a cross-sectional view, a width of a bottom surface of the second layer may be wider than a width of a top surface of the first layer.

In an embodiment, the sensing area may further include a hole auxiliary layer overlapping the light-emitting areas, the light-receiving area, and the non-light-emitting area, where the hole auxiliary layer is disconnected by the first and second separators, emitting layers respectively disposed on portions of the hole auxiliary layer overlapping the light-emitting areas, a light-receiving layer disposed on a portion of the hole auxiliary layer overlapping the light-receiving area, an electron auxiliary layer disposed on the hole auxiliary layer, the emitting layers, and the light-receiving layer, where the electron auxiliary layer is disconnected by the first and second separators, and a cathode disposed on the electron auxiliary layer, where the cathode is disconnected by the first and second separators.

In an embodiment, the light-emitting areas may include a first light-emitting area which emits light of a first color, a second-first light-emitting area which emits light of a second color, a second-second light-emitting area which emits light of the second color, and a third light-emitting area which emits light of a third color.

In an embodiment, in a plan view, the third light-emitting area, the first light-emitting area, the second-second light-emitting area, and the second-first light-emitting area may each be disposed above, below, to the left of, and to the right of the light-receiving area.

An electronic device according to an embodiment includes a processor to provide input image data and a display device to display an image based on the input image data. In such an embodiment, the display device includes a display area and a sensing area overlapping at least a portion of the display area. In such an embodiment, the sensing area includes a light-emitting area, a light-receiving area spaced from the light-emitting area, a non-light-emitting area surrounding the light-emitting area and the light-receiving area, and a separator disposed in the non-light-emitting area and adjacent to the light-receiving area.

### BRIEF DESCRIPTION OF THE DRAWINGS

The above and other features of embodiments of the invention will become more apparent by describing in further detail embodiments thereof with reference to the accompanying drawings, in which:

FIGS. 1 and 2 are plan views of a display device according to embodiments.

FIG. 3 is a cross-sectional view of a display device according to an embodiment.

FIG. 4 is a circuit diagram of a sub-pixel and a light-sensing pixel according to an embodiment.

FIG. 5 is an enlarged view of the area EA of FIG. 2 according to an embodiment.

FIG. 6 is a cross-sectional view taken along line I-I′ of FIG. 5.

FIG. 7 is an enlarged view of the area EA of FIG. 2 according to another embodiment.

FIG. 8 is a cross-sectional view taken along line II-II′ of FIG. 7.

FIG. 9 is an enlarged view of the area EA of FIG. 2 according to another embodiment.

FIG. 10 is an enlarged view of the area EA of FIG. 2 according to another embodiment.

FIG. 11 is an enlarged view of the area EA of FIG. 2 according to another embodiment.

FIGS. 12 to 17 are cross-sectional views illustrating a method for manufacturing a display device according to an embodiment.

FIG. 18 is a block diagram of an electronic device according to an embodiment.

FIG. 19 shows schematic views of various embodiments of an electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. Throughout the specification, when one part is said to be “connected” to another part, this includes not only “direct connection” but also “indirect connection” with other elements in between.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “At least one of X, Y, and Z” or “at least one selected from X, Y, and Z” may be interpreted as one of X, one of Y, one of Z, or any combination of two or more of X, Y, and Z (for example, XYZ, XY, YZ, ZZ). “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Terms like “below,” “above,” and other spatially relative terms may be used for explanatory purposes and to describe one element or feature's relationship to other elements or features as illustrated in the drawings. Spatially relative terms are intended to encompass different orientations of the element in use, during operation, and/or during manufacturing in addition to the direction depicted in the drawings. For example, if the device in the drawings is turned over, an element described as being “below” other elements or features would be oriented “above” them. Therefore, the term “below” may include both directions, above and below, in an embodiment. Moreover, the device may be oriented in other directions (for example, turned 90 degrees or in another orientation), and accordingly, the spatially relative terms used herein are to be interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

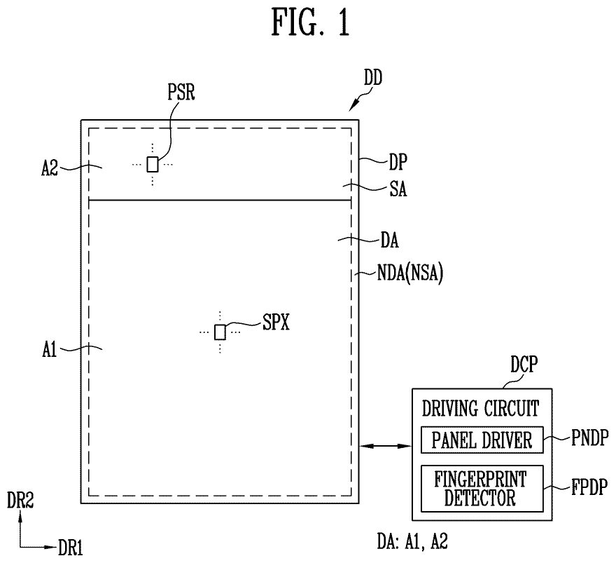

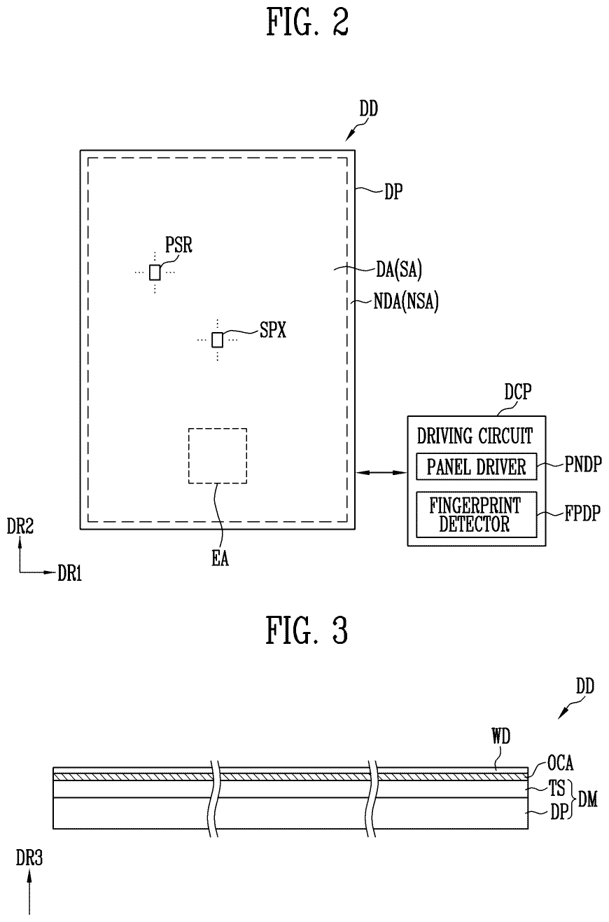

FIGS. 1 and 2 are plan views of display devices according to embodiments. In FIGS. 1 and 2, according to embodiments, a display panel DP and a driving circuit DCP for driving the display panel DP included in the display devices DD are shown. For convenience of illustration, the display panel DP and the driving circuit DCP are shown separately in FIGS. 1 and 2, but embodiments are not limited thereto. In another embodiment, for example, all or part of the driving circuit DCP may be integrated with the display panel DP.

Referring to FIGS. 1 and 2, an embodiment of the display device DD may include a display panel DP and a driving circuit DCP for driving the display panel DP.

The display device DD may be provided in various shapes. In an embodiment, for example, the display device DD may be provided as a rectangular plate having two pairs of parallel sides in a plan view or when viewed in a thickness direction of the display device DD, although embodiments are not necessarily limited to this. In an embodiment where the display device DD is provided as a rectangular plate, one pair of sides among the two pairs of sides may be longer than the other pair of sides. FIGS. 1 and 2 show an embodiment of the display device DD in a rectangular shape having one pair of long sides and one pair of short sides, with the extension direction of the pair of long sides is a second direction DR2, and the extension direction of the pair of short sides is a first direction DRI crossing the second direction DR2. According to an embodiment, the display device DD provided as a rectangular plate may have rounded corners where one long side and one short side meet.

The display device DD may be a flat display device, a flexible display device, a curved display device, a foldable display device, or a bendable display device. Additionally, the display device DD may be applied to transparent display devices, head-mounted display devices, wearable display devices, etc.

The display panel DP may include a display area DA and a non-display area NDA. The display area DA may display an image, and the non-display area NDA may be located on at least one side of the display area DA. In an embodiment, for example, the non-display area NDA may surround the display area DA in a plan view.

The display area DA may include sub-pixels SPX. Each sub-pixel SPX may include at least one light-emitting element. The light-emitting element may be a light-emitting unit including organic light-emitting diodes or ultra-small inorganic light-emitting diodes ranging in micro to nano scale, although embodiments are not necessarily limited to this. The display device DD may display an image on the display area DA by driving the sub-pixels SPX in response to the input image data.

The non-display area NDA is an area surrounding at least one side of the display area DA and may be the remaining area of the display device DD excluding the display area DA. The non-display area NDA may include wiring areas, pad areas, and/or various dummy areas.

Referring to FIG. 1, in an embodiment, a part of the display area DA may include or be set as a sensing area SA that may detect, for example, a user's fingerprint. That is, at least a part of the display area DA may be the sensing area SA. In an embodiment, for example, the display area DA may be divided into a first area A1 and a second area A2 in the second direction DR2, with the second area A2 set as the sensing area SA. In such an embodiment, the first area A1 and the non-display area NDA may be non-sensing areas NSA.

Referring to FIG. 2, in another embodiment, the entire display area DA may be set as the sensing area SA. In such an embodiment, the non-display area NDA may be the non-sensing area NSA.

In such an embodiment, light-sensing pixels PSR (or light sensors) may be spaced apart from the sub-pixels SPX and distributed across the entire display area DA. However, embodiments are not necessarily limited to this. In an embodiment, for example, as shown in FIG. 1, the light-sensing pixels PSR may be placed only in the second area A2. Additionally, light-sensing pixels PSR may also be positioned in at least a part of the non-display area NDA.

Each of the light-sensing pixels PSR may include a light-receiving element that includes a light-receiving layer. Within the display area DA, the light-receiving layers of the light-receiving elements may be spaced apart from the light-emitting layers of the light-emitting elements.

The light-sensing pixels PSR may sense light emitted from a light source (for example, a light-emitting element) that is reflected by an external object (for example, a user's finger). In an embodiment, for example, a user's fingerprint may be sensed through each of the light-sensing pixels PSR. Hereinafter, for convenience of description, embodiments where the light-sensing pixels PSR are used for fingerprint sensing will be mainly described as an example, but embodiments are not necessarily limited to this. In another embodiment, for example, the light-sensing pixels PSR may sense various biometric information such as iris, veins, etc. Additionally, the light-sensing pixels PSR may also sense external light and perform functions of a gesture sensor, motion sensor, proximity sensor, light sensor, image sensor, or the like.

The driving circuit DCP may drive the display panel DP. In an embodiment, for example, the driving circuit DCP may output data signals corresponding to image data to the display panel DP, output driving signals for the light-sensing pixels PSR, and receive electrical signals (e.g., sensing signals) from the light-sensing pixels PSR. The driving circuit DCP may use these electrical signals to detect the shape of a user's fingerprint.

The driving circuit DCP may include a panel driving part PNDP and a fingerprint detection part FPDP (or sensor driving part). Although FIGS. 1 and 2 show an embodiment where the panel driving part PNDP and the fingerprint detection part FPDP are separate components, embodiments are not necessarily limited to this. In another embodiment, for example, at least part of the fingerprint detection part FPDP may be integrated with the panel driving part PNDP or may operate in conjunction with it.

The panel driving part PNDP may sequentially scan the sub-pixels SPX in the display area DA and supply data signals corresponding to the image data signals to the sub-pixels SPX. In this case, the display panel DP may display an image corresponding to the image data.

The panel driving part PNDP may supply driving signals for fingerprint detection to the sub-pixels SPX. These driving signals may be provided to the sub-pixels SPX to enable them to emit light and act as a light source for the light-sensing pixels PSR. Additionally, the panel driving part PNDP may also supply the driving signals for fingerprint detection and/or other driving signals to the light-sensing pixels PSR. However, embodiments are not necessarily limited to this. In an embodiment, for example, the driving signals for fingerprint detection may be provided by the fingerprint detection part FPDP.

The fingerprint detection part FPDP may detect biometric information such as a user's fingerprint based on the sensing signals received from the light-sensing pixels PSR. The fingerprint detection part FPDP may also supply these driving signals to the light-sensing pixels PSR and/or sub-pixels SPX.

FIG. 3 is a cross-sectional view of a display device according to an embodiment. For convenience of illustration, in FIG. 3, the thickness direction of the display device DD is shown as a third direction DR3.

Referring to FIG. 3, an embodiment of the display device DD may include a display module DM and a window WD.

The display module DM may include a display panel DP and a touch sensor TS.

The touch sensor TS may be directly placed on the display panel DP or may be placed on the display panel DP with a separate layer therebetween, such as an adhesive layer or a substrate (or, insulating layer).

The display panel DP may display an image. The display panel DP may be a self-emitting display panel such as an organic light emitting display panel (OLED panel). However, embodiments are not necessarily limited to this. For example, the display panel DP may be a non-emission display panel such as a liquid crystal display panel (LCD panel), an electro-phoretic display panel (EPD panel), or an electro-wetting display panel (EWD panel). In an embodiment where the display panel DP is a non-emission display panel, the display device DD may further include a backlight unit to supply light to the display panel DP.

The touch sensor TS may be placed on the surface where the image from the display panel DP is emitted, to allow the display device DD to receive touch inputs from a user. The touch sensor TS may recognize touch events on the display device DD via a user's hand or a separate input tool. The touch sensor TS may detect touch events using a capacitive method. In an embodiment, for example, the touch sensor TS may detect touch inputs using either a mutual capacitance method or a self-capacitance method.

A window WD may be provided on the display module DM to protect the exposed surface of the display module DM. The window WD may protect the display module DM from external impacts and provide an input and/or display surface to the user. The window WD may be bonded to the display module DM using an optically clear adhesive OCA.

The window WD may have a multilayer structure selected from glass substrates, plastic films, or plastic substrates. Such a multilayer structure may be formed through a continuous process or an adhesive process using adhesive layers. The window WD may be entirely or partially flexible.

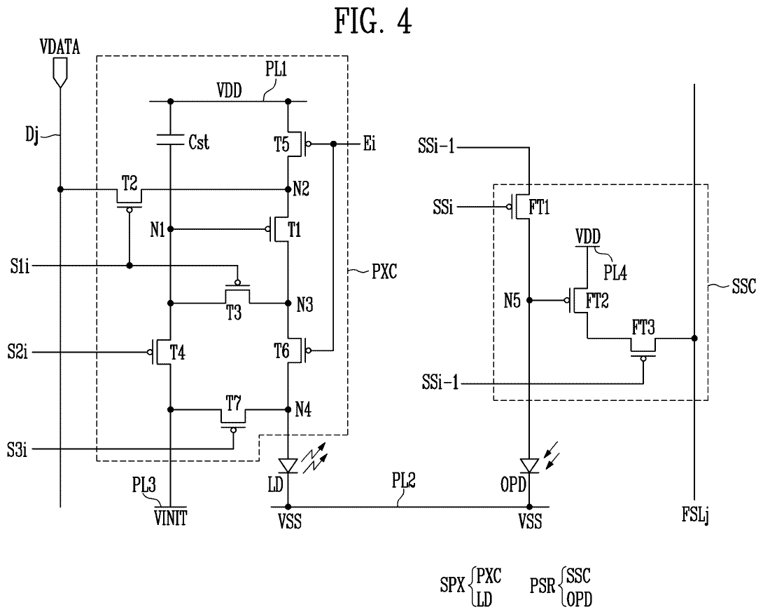

FIG. 4 is a circuit diagram of a sub-pixel and a light-sensing pixel according to an embodiment. For convenience of illustration and description, FIG. 4 shows a sub-pixel SPX located in an i-th pixel row (or, the i-th horizontal line) and connected to a j-th data line Dj, and a light-sensing pixel PSR located in the i-th pixel row and connected to the j-th fingerprint detection line FSLj (or, readout line), where i and j are natural numbers.

Referring to FIG. 4, in an embodiment, the sub-pixel SPX may include a pixel circuit PXC and an associated light-emitting element LD. In such an embodiment, the light-sensing pixel PSR may include a sensor circuit SSC and an associated light-receiving element OPD.

One electrode (or anode) of the light-emitting element LD may be connected to a fourth node N4, and the other electrode (or cathode) of the light-emitting element LD may be connected to the second driving power source VSS. The light-emitting element LD may emit light of a predetermined luminance in response to the current (or drive current) supplied from the pixel circuit PXC.

In an embodiment, the light-emitting element LD may be an organic light-emitting diode that includes an organic light-emitting layer. However, embodiments are not necessarily limited to this. In another embodiment, for example, the light-emitting element LD may be an inorganic light-emitting element formed from inorganic materials or a light-emitting element composed of a combination of inorganic and organic materials.

The light-receiving element OPD may be an organic photodiode. One electrode (or first sensor electrode) of the light-receiving element OPD may be connected to the fifth node N5, and the other electrode (or second sensor electrode) of the light-receiving element OPD may be connected to the second driving power source VSS. The light-receiving element OPD may generate carriers including free electrons and holes based on the intensity of light incident on the light-receiving layer, and produce a current (or photo current) due to the movement of these carriers.

The pixel circuit PXC may include a first transistor T1, a second transistor T2, a storage capacitor Cst, and a light-emitting element LD. Additionally, the pixel circuit PXC may further include a third transistor T3, a fourth transistor T4, a fifth transistor T5, a sixth transistor T6, and a seventh transistor T7.

A gate electrode of the first transistor T1 (or drive transistor) may be connected to a first node N1, a first electrode of the first transistor T1 may be connected to a second node N2, and a second electrode of the first transistor Tl may be connected to a third node N3.

The first transistor T1 may control the current flowing from the first driving power source VDD through the light-emitting element LD to the second driving power source VSS in response to the voltage at the first node N1. In such an embodiment, the first driving power source VDD may be set to a higher voltage than the second driving power source VSS.

The second transistor T2, also referred to as the switching transistor, may be connected between the j-th data line Dj connected to the pixel PXL (hereinafter referred to as ‘data line’) and the second node N2. A gate electrode of the second transistor T2 may be connected to an i-th first scan line S1i connected to the pixel PXL (hereinafter referred to as ‘first scan line’). The second transistor T2 turns on when a first scan signal is supplied to the first scan line S1i, thereby electrically connecting the data line Dj and the second node N2 to each other.

The third transistor T3, also referred to as the compensation transistor, may be connected between the second electrode of the first transistor T1 (or the third node N3) and a gate electrode thereof (or the first node N1). The gate electrode of the third transistor T3 may be connected to the first scan line S1i. The third transistor T3 turns on when a first scan signal is supplied to the first scan line S1i, electrically connecting the second electrode and the gate electrode of the first transistor T1 (or the first node N1 and the third node N3) to each other. Therefore, the timing when the second electrode of the first transistor T1 is connected to the gate electrode thereof may be controlled by the first scan signal. When the third transistor T3 turns on, the first transistor T1 may be connected in a diode configuration.

The fourth transistor T4, also referred to as the first initialization transistor, may be connected between the first node N1 (or the gate electrode of the first transistor T1) and a third power line PL3 to which an initialization voltage VINIT is applied. A gate electrode of the fourth transistor T4 may be connected to an i-th second scan line S2i (hereinafter referred to as ‘second scan line’). The fourth transistor T4 turns on in response to a second scan signal supplied to the second scan line S2i, thereby supplying the initialization voltage VINIT to the first node N1. Here, the initialization voltage VINIT may be set to a lower voltage than the data voltage VDATA supplied to the data line Dj. As a result, the gate voltage of the first transistor T1 (or the first node N1) may be initialized to the initialization voltage VINIT by the turning on of the fourth transistor T4.

The fifth transistor T5, also referred to as the first emission control transistor, may be connected between the first power line PL1 (or first driving voltage line) and the second node N2. The gate electrode of the fifth transistor T5 may be connected to an i-th emission control line Ei (hereinafter referred to as ‘emission control line’). The fifth transistor T5 turns on when an emission control signal is supplied to the emission control line Ei, and turns off otherwise.

The sixth transistor T6, also referred to as the second emission control transistor, may be connected between the second electrode of the first transistor T1 (or the third node N3) and the fourth node N4. A gate electrode of the sixth transistor T6 may be connected to the emission control line Ei. The sixth transistor T6 may be controlled substantially the same as the fifth transistor T5.

The fifth transistor T5 and the sixth transistor T6 may turn on in response to the emission control signal supplied through the emission control line Ei, thereby forming a path for the drive current between the first power line PL1 and the fourth node N4 (or between the first power line PL1 and the second power line PL2).

FIG. 4 shows an embodiment where the fifth transistor T5 and the sixth transistor T6 are connected to the same emission control line Ei; however, embodiments are not necessarily limited to this. In another embodiment, for example, the fifth transistor T5 and the sixth transistor T6 may be connected to separate emission control lines that receive different emission control signals.

The seventh transistor T7, also referred to as the second initialization transistor, may be connected between the fourth node N4 and the third power line PL3. A gate electrode of the seventh transistor T7 may be connected to an i-th third scan line S3i (hereinafter referred to as ‘third scan line’). The seventh transistor T7 turns on when a third scan signal is supplied to the third scan line S3i, thereby supplying the initialization voltage VINIT to the fourth node N4.

The storage capacitor Cst may be connected between the first power line PL1 and the first node N1. The storage capacitor Cst may store the differential voltage between the voltage of the first driving power source VDD provided by the first power line PL1 and a voltage obtained by subtracting the absolute threshold voltage of the first transistor T1 from the voltage at the first node N1.

A first scan signal may be supplied after a second scan signal is provided. In an embodiment, for example, the second scan signal and the first scan signal may be supplied with a one-horizontal-period difference. However, embodiments are not necessarily limited to this configuration.

In an embodiment, the third scan signal may be supplied simultaneously with the first scan signal. However, embodiments are not necessarily limited to this. In another embodiment, for example, the first scan signal may be supplied after the third scan signal has been provided, and the interval between the supply of the third scan signal and the first scan signal may be one horizontal period. Additionally, the third scan signal may also be supplied after the first scan signal has been provided.

The sensor circuit SSC include a first sensor transistor FT1, a second sensor transistor FT2, and a third sensor transistor FT3.

The second sensor transistor FT2 and the third sensor transistor FT3 may be connected in series between a sensing power line PL4 (or the fourth power line) and a j-th fingerprint detection line FSLj (hereinafter referred to as ‘fingerprint detection line’).

The first sensor transistor FT1 may be connected between an (i−1)-th sensing scan line SSi−1 (hereinafter referred to as ‘previous sensing scan line’) and a fifth node N5 (or the first electrode of the light-receiving element OPD). A gate electrode of the first sensor transistor FT1 may be connected to an i-th sensing scan line SSi (hereinafter referred to as ‘sensing scan line’). The first sensor transistor FT1 may turn on in response to the sensing scan signal supplied to the sensing scan line SSi, thereby supplying the voltage from the previous sensing scan line SSi−1 to the fifth node N5. The first sensor transistor FT1 may be utilized for voltage reset (or initialization) at the fifth node N5.

A gate electrode of the second sensor transistor FT2 may be connected to the fifth node N5. The second sensor transistor FT2 may generate a sensing current that flows from the sensing power line PL4 to the fingerprint detection line FSLj based on the voltage at the fifth node N5, which is induced by the photocurrent generated by the light-receiving element OPD.

The gate electrode of the third sensor transistor FT3 may be connected to the previous sensing scan line SSi−1. The third sensor transistor FT3 turns on when a sensing scan signal is supplied to the previous sensing scan line SSi−1, thereby electrically connecting the second sensor transistor FT2 and the fingerprint detection line FSLj to each other. Consequently, the sensing signal (or sensing current) may be supplied to the fingerprint detection part FPDP (refer to FIGS. 1 and 2) through the fingerprint detection line FSLj.

In an embodiment, the first to seventh transistors T1 to T7 included in the pixel circuit PXC and the first to third sensor transistors FT1 to FT3 included in the sensor circuit SSC may be P-type transistors (for example, p-channel metal-oxide-semiconductor (PMOS) transistors), but embodiments are not necessarily limited to this. In another embodiment, for example, at least one of the first to seventh transistors T1 to T7 and the first to third sensor transistors FT1 to FT3 may be implemented as N-type transistors (for example, NMOS transistors). In an embodiment where the first to seventh transistors T1 to T7 and the first to third sensor transistors FT1 to FT3 are N-type, the positions of the source and drain regions (or electrodes) may be reversed.

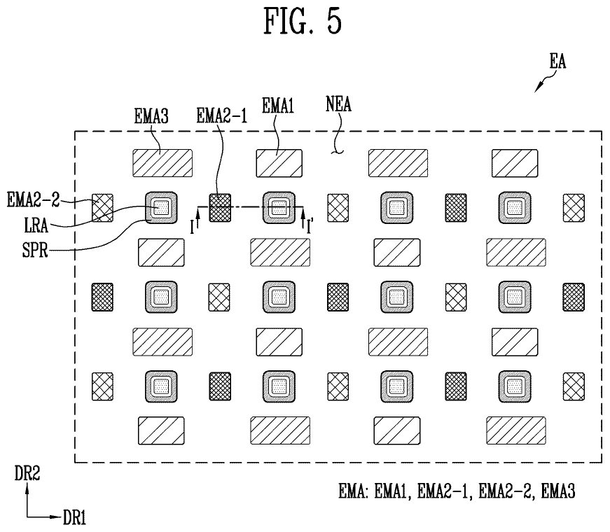

FIG. 5 is an enlarged view of the area EA of FIG. 2 according to an embodiment. The area EA in FIG. 2 may represent a part of the sensing area SA (or display area DA) of the display panel DP.

Referring to FIG. 5, in an embodiment, the sensing area SA may include emission areas EMA, light-receiving areas LRA, and non-emission area NEA. The emission areas EMA may include first emission areas EMA1, second-first emission areas EMA2−1, second-second emission areas EMA2−2, and third emission areas EMA3. The first emission areas EMA1 may emit light of a first color (for example, red). The second-first emission areas EMA2−1 and second-second emission areas EMA2−2 may emit light of a second color (for example, green). The third emission areas EMA3 may emit light of a third color (for example, blue). The light-receiving areas LRA may receive and sense light reflected and incident from an external object (for example, a user's finger). The non-emission area NEA may be the remaining areas of the sensing area SA excluding the emission areas EMA and light-receiving areas LRA, surrounding the emission areas EMA and light-receiving areas LRA.

The first emission areas EMA1 and third emission areas EMA3 may be alternately arranged along the first direction DRI and the second direction DR2. The second-first emission areas EMA2−1 and second-second emission areas EMA2−2 may also be alternately arranged along the first direction DR1 and the second direction DR2. The second-first emission areas EMA2−1 and second-second emission areas EMA2−2 may be placed in different matrices than the first emission areas EMA1 and third emission areas EMA3. In an embodiment, for example, the first emission areas EMA1 and third emission areas EMA3 may be arrayed in odd rows and even columns, and the second-first emission areas EMA2−1 and second-second emission areas EMA2−2 may be arrayed in even rows and odd columns. The light-receiving areas LRA may be arranged in a matrix form along the first direction DRI and the second direction DR2. The light-receiving areas LRA may be arrayed in the same row as the second-first emission areas EMA2−1 and second-second emission areas EMA2−2, and in the same column as the first emission areas EMA1 and third emission areas EMA3.

Emission areas EMA may be arranged to surround light-receiving areas LRA. In a plan view, for example, with reference to one light-receiving area, referred to as ‘first light-receiving area’, the first emission area EMA1 may be positioned below the first light-receiving area, second-first emission area EMA2−1 may be positioned to the right of (or at a right side of) the first light-receiving area, second-second emission area EMA2−2 may be positioned to the left of (or at a left side of) the first light-receiving area, and third emission area EMA3 may be positioned above the first light-receiving area. Consequently, third emission area EMA3, first emission area EMA1, second-second emission area EMA2−2, and second-first emission area EMA2−1 may respectively be disposed above, below, to the left of, and to the right of the first light-receiving area LRA. In this arrangement, based on the light-receiving areas disposed above, below, to the left of, and to the right of the first light-receiving area, referred to as ‘second light-receiving areas’, the first emission area EMA1 may be positioned above each of the second light-receiving areas, second-first emission area EMA2−1 on the left of each, the second-second emission area EMA2−2 on the right, and the third emission area EMA3 below each of the second light-receiving areas. Thus, the first emission area EMA1, the third emission area EMA3, the second-first emission area EMA2−1, and the second-second emission area EMA2−2 may each be areas disposed above, below, to the left of, and to the right of the second light-receiving areas. However, embodiments are not necessarily limited to this configuration, and the arrangement of emission areas EMA and light-receiving areas LRA may be variously modified.

Separators SPR may be provided in non-emission area NEA. Each separator SPR may be positioned adjacent to a corresponding one of the light-receiving areas LRA. Separators SPR may entirely surround each light-receiving area LRA in a plan view. However, embodiments are not necessarily limited to this configuration. In another embodiment, for example, separators SPR may partially surround each light-receiving area LRA.

In an embodiment, as shown in FIG. 5, each separator SPR may be positioned around each light-receiving area LRA and may not be positioned around each emission area EMA.

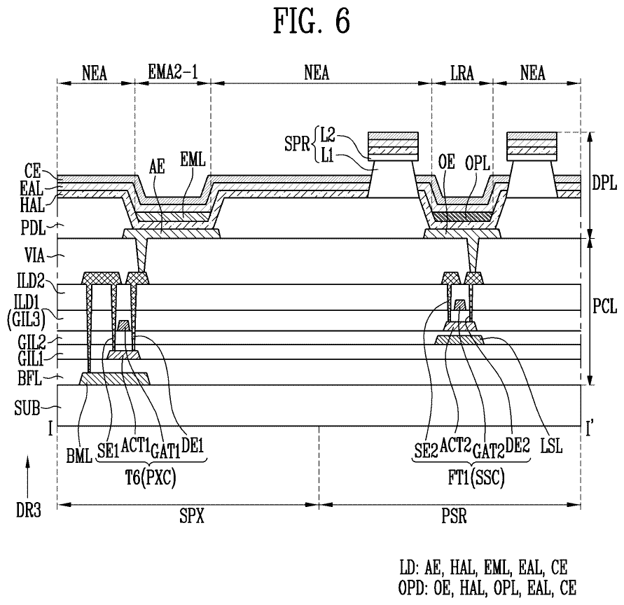

FIG. 6 is a cross-sectional view taken along line I-I′ of FIG. 5. In FIG. 6, a stacked structure of the sub-pixels SPX including the second-first emission areas EMA2−1 and the non-emission area NEA around the second-first emission areas EMA2−1, as well as the light-sensing pixels PSR including the light-receiving areas LRA and the non-emission area NEA around the light-receiving areas LRA on a substrate SUB is depicted.

Referring to FIG. 6, in an embodiment, the substrate SUB may include a silicon wafer substrate formed using semiconductor processes. The substrate SUB may include semiconductor materials suitable for forming circuit elements. In an embodiment, for example, the semiconductor material may include silicon, germanium, and/or silicon-germanium. The substrate SUB may also be provided from a bulk wafer, an epitaxial layer, a Silicon On Insulator (SOI) layer, or a semiconductor on insulator (SeOI) layer. However, embodiments are not limited to this. In another embodiment, for example, the substrate SUB may include a glass substrate or a polyimide (PI) substrate.

A pixel circuit layer PCL may be positioned on the substrate SUB. The pixel circuit layer PCL may include a bottom metal layer BML, a buffer layer BFL, a first active pattern ACT1, a first gate insulating layer GIL1, a light shielding layer LSL, a second gate insulating layer GIL2, a first gate electrode GAT1, a second active pattern ACT2, a first interlayer dielectric layer ILD1 (or third gate insulating layer GIL3), a second gate electrode GAT2, a second interlayer dielectric layer ILD2, a first source electrode SE1, a first drain electrode DE1, a second source electrode SE2, a second drain electrode DE2, and a via layer VIA.

The bottom metal layer BML may be positioned on the substrate SUB. The bottom metal layer BML may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, for example, the bottom metal layer BML may be a single layer of molybdenum, a double-layer structure in which molybdenum and titanium layers are stacked, or a triple-layer structure in which titanium, aluminum, and titanium layers are stacked.

A buffer layer BFL may be positioned on the bottom metal layer BML. The buffer layer BFL may be positioned on the substrate SUB to cover the bottom metal layer BML. The buffer layer BFL may be an inorganic insulating layer that includes inorganic insulators such as silicon nitride and/or silicon oxide. The buffer layer BFL may have a single-layer or multi-layer structure, each layer therein including at least one selected from the aforementioned materials.

The first active pattern ACT1 may be positioned on the buffer layer BFL. The first active pattern ACT1 may overlap the bottom metal layer BML in the third direction DR3. The first active pattern ACTI may include an oxide semiconductor. In an embodiment, for example, the first active pattern ACTI may include indium gallium zinc oxide (IGZO) or indium tin gallium zinc oxide (ITGZO), but embodiments are not necessarily limited to these materials.

The first active pattern ACT1 may include a channel area, and source and drain areas adjacent to the channel area. The channel area may be an undoped area and may have lower conductivity compared to the source and drain areas. The channel area is where carriers (holes or electrons) flow and may be located at the center of the first active pattern ACT1. The source and drain areas may be doped areas with higher conductivity compared to the channel area. In an embodiment, for example, the source and drain areas may be doped with an n-type dopant, but embodiments are not necessarily limited to this. The source area is where carriers are supplied and may be located on one side of the channel area (for example, on the left). The drain area is where carriers supplied from the source area are discharged after passing through the channel area and may be located on the opposite side of the channel area (for example, on the right).

A first gate insulating layer GILI may be positioned on the first active pattern ACT1. The first gate insulating layer GILI may be positioned on the buffer layer BFL to cover the first active pattern ACT1. The first gate insulating layer GILI may be an inorganic insulating layer that includes an inorganic insulator such as silicon oxide, silicon nitride, and/or silicon oxynitride. The first gate insulating layer GILI may have a single-layer or multi-layer structure, each layer therein including at least one selected from the aforementioned materials.

A light shielding layer LSL may be positioned on the first gate insulating layer GIL1. The light shielding layer LSL may block light to prevent light from reaching the second active pattern ACT2. The light shielding layer LSL may include metal to reflect light. However, embodiments are not necessarily limited to this. In an embodiment, for example, the light shielding layer LSL may include a resin mixed with carbon to absorb light.

A second gate insulating layer GIL2 may be positioned on the light shielding layer LSL. The second gate insulating layer GIL2 may be positioned on the first gate insulating layer GIL1 to cover the light shielding layer LSL. The second gate insulating layer GIL2 may be an inorganic insulating layer that includes inorganic insulators such as silicon oxide, silicon nitride, and/or silicon oxynitride. The second gate insulating layer GIL2 may have a single-layer or multi-layer structure, each layer therein including at least one selected from the aforementioned materials.

A first gate electrode GAT1 may be positioned on the second gate insulating layer GIL2. The first gate electrode GAT1 may overlap the channel area of the first active pattern ACT1 in the third direction DR3. The first gate electrode GATI may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The first gate electrode GAT1 may have a single layer or multi-layer structure, each layer therein including at least one selected from the aforementioned materials.

A second active pattern ACT2 may be positioned on the second gate insulating layer GIL2. The second active pattern ACT2 may overlap the light shielding layer LSL in the third direction DR3. The second active pattern ACT2 may include an oxide semiconductor. In an embodiment, for example, the second active pattern ACT2 may include indium gallium zinc oxide (IGZO) or indium tin gallium zinc oxide (ITGZO), but embodiments are not necessarily limited to these materials.

The second active pattern ACT2 may include a channel area and source and drain areas adjacent to the channel area. The channel, source, and drain areas of the second active pattern ACT2 may be substantially identical to those of the first active pattern ACT1, so any repetitive detailed description thereof will be omitted.

A first interlayer dielectric layer ILD1 may be positioned on the first gate electrode GAT1 and the second active pattern ACT2. The first interlayer dielectric layer ILD1 may be positioned on the second gate insulating layer GIL2 to cover the first gate electrode GAT1 and the second active pattern ACT2. The first interlayer dielectric layer ILD1 may be an inorganic insulating layer that includes inorganic insulators such as silicon oxide, silicon nitride, and/or silicon oxynitride. The first interlayer dielectric layer ILD1 may have a single-layer or multi-layerstructure, each layer therein including at least one selected from the aforementioned materials. The first interlayer dielectric layer ILD1 may also be referred to as the third gate insulating layer GIL3.

A second gate electrode GAT2 may be positioned on the first interlayer dielectric layer ILD1 (or third gate insulating layer GIL3). The second gate electrode GAT2 may overlap with the channel area of the second active pattern ACT2 in the third direction DR3. The second gate electrode GAT2 may include materials such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The second gate electrode GAT2 may have a single-layer or multi-layer structure, each layer therein including at least one selected from the aforementioned materials.

A second interlayer dielectric layer ILD2 may be positioned on the second gate electrode GAT2. The second interlayer dielectric layer ILD2 may be positioned on the first interlayer dielectric layer ILD1 (or third gate insulating layer GIL3) to cover the second gate electrode GAT2. The second interlayer dielectric layer ILD2 may be an inorganic insulating layer that includes inorganic insulators such as silicon oxide, silicon nitride, and/or silicon oxynitride. The second interlayer dielectric layer ILD2 may have a single-layer or multi-layer structure, each layer therein including at least one selected from the aforementioned materials.

First source electrode SE1 and first drain electrode DE1 may be positioned on the second interlayer dielectric layer ILD2. The first source electrode SE1 may be electrically connected to the source area of the first active pattern ACT1 through a contact hole defined (or formed) through the first gate insulating layer GIL1, second gate insulating layer GIL2, first interlayer dielectric layer ILD1 (or third gate insulating layer GIL3), and second interlayer dielectric layer ILD2. Additionally, the first source electrode SE1 may be electrically connected to the bottom metal layer BML through a contact hole defined through the buffer layer BFL, first gate insulating layer GIL1, second gate insulating layer GIL2, first interlayer dielectric layer ILD1 (or third gate insulating layer GIL3), and second interlayer dielectric layer ILD2. The first drain electrode DE1 may be electrically connected to the drain area of the first active pattern ACT1 through a contact hole defined through the first gate insulating layer GIL1, second gate insulating layer GIL2, first interlayer dielectric layer ILD1 (or third gate insulating layer GIL3), and second interlayer dielectric layer ILD2.

First source electrode SE1 and first drain electrode DE1 may include materials such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The first source electrode SE1 and first drain electrode DE1 may have a single-layer or multi-layer structure, each layer therein including at least one selected from the aforementioned materials.

The aforementioned first active pattern ACT1, first gate electrode GAT1, first source electrode SE1, and first drain electrode DE1 may constitute the sixth transistor T6 of the pixel circuit PXC (see FIG. 4).

Second source electrode SE2 and second drain electrode DE2 may be positioned on the second interlayer dielectric layer ILD2. The second source electrode SE2 may be electrically connected to the source area of the second active pattern ACT2 through a contact hole defined through the first interlayer dielectric layer ILD1 (or third gate insulating layer GIL3) and second interlayer dielectric layer ILD2. The second drain electrode DE2 may be electrically connected to the drain area of the second active pattern ACT2 through a contact hole defined through the first interlayer dielectric layer ILD1 (or third gate insulating layer GIL3) and second interlayer dielectric layer ILD2.

Second source electrode SE2 and second drain electrode DE2 may include materials such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). Second source electrode SE2 and second drain electrode DE2 may have a single-layer or multi-layer structure, each layer therein including at least one selected from the aforementioned materials.

The aforementioned second active pattern ACT2, second gate electrode GAT2, second source electrode SE2, and second drain electrode DE2 may constitute the first sensor transistor FT1 of the sensor circuit SSC (see FIG. 4).

A via layer VIA may be positioned on first source electrode SE1, first drain electrode DE1, second source electrode SE2, and second drain electrode DE2. The via layer VIA may be positioned on the second interlayer dielectric layer ILD2 to cover first source electrode SE1, first drain electrode DE1, second source electrode SE2, and second drain electrode DE2. The via layer VIA may be an organic insulating layer that includes organic insulators such as polyimide and/or siloxane. The via layer VIA may have a single-layer or multi-layer structure, each layer therein including at least one selected from the aforementioned materials.

A display device layer DPL may be positioned on the pixel circuit layer PCL. The display device layer DPL may include an anode AE, a sensing electrode OE, a pixel defining layer PDL, separators SPR, a hole auxiliary layer HAL, an emission layer EML, a light-receiving layer OPL, an electron auxiliary layer EAL, and a cathode CE.

The anode AE may be positioned on the via layer VIA. The anode AE may be electrically connected to the first drain electrode DE1 through a contact hole defined through the via layer VIA. The anode AE may include transparent conductive materials such as indium tin oxide (ITO), indium zinc oxide (IZO), zinc oxide, indium gallium zinc oxide (IGZO), and/or indium tin zinc oxide (ITZO). However, embodiments are not necessarily limited to these. In an embodiment, for example, the anode AE may include titanium nitride.

A sensing electrode OE may be positioned on the via layer VIA. The sensing electrode OE may be electrically connected to the second drain electrode DE2 through a contact hole defined through the via layer VIA. The sensing electrode OE may include transparent conductive materials such as indium tin oxide (ITO), indium zinc oxide (IZO), zinc oxide, indium gallium zinc oxide (IGZO), and/or indium tin zinc oxide (ITZO). However, embodiments are not necessarily limited to these materials. In an embodiment, for example, the sensing electrode OE may include titanium nitride.

A pixel defining layer PDL may be positioned over portions of the anode AE and the sensing electrode OE. The pixel defining layer PDL may be positioned on the via layer VIA to partially cover the anode AE and the sensing electrode OE. The pixel defining layer PDL may include multiple inorganic insulating layers. Each of the multiple inorganic insulating layers may include at least one selected from silicon oxide and silicon nitride. In an embodiment, for example, the pixel defining layer PDL may include sequentially stacked first to third inorganic insulating layers, where the first to third inorganic insulating layers may include silicon nitride, silicon oxide, and silicon nitride, respectively. However, embodiments are not necessarily limited to these configurations. In an embodiment, for example, the pixel defining layer PDL may include multiple organic insulating layers, each layer therein including at least one selected from polyimide, polyamide, acrylic resin, benzocyclobutene, and phenolic resin.

Separators SPR may be positioned on the pixel defining layer PDL. Separators SPR are provided in the non-emission area NEA and may be adjacent to the light-receiving area LRA. The adjacency of separators SPR to the light-receiving area LRA may mean that separators SPR are positioned closer to the light-receiving area LRA than to the second-first emission area EMA2−1. Separators SPR may disrupt the hole auxiliary layer HAL, electron auxiliary layer EAL, and cathode CE provided in the non-emission area NEA adjacent to the light-receiving area LRA. Consequently, lateral leakage between sub-pixels SPX and light-sensing pixels PSR may be effectively prevented or substantially reduced, thereby increasing the operational reliability of the light-sensing pixels PSR.

Separators SPR may have a multi-layer structure. In an embodiment, for example, the separators SPR may include a first layer L1 and a second layer L2 positioned on the first layer L1. In a cross-sectional view, the first layer L1 may have a tapered shape with a width which gradually decreases in the third direction DR3. In an embodiment, for example, the width of a bottom surface of the first layer L1 may be greater than the width of a top surface thereof. In a cross-sectional view, the second layer L2 may have a rectangular shape, but embodiments are not necessarily limited to this. The width of the bottom surface of the second layer L2 may be greater than the width of the top surface of the first layer L1.

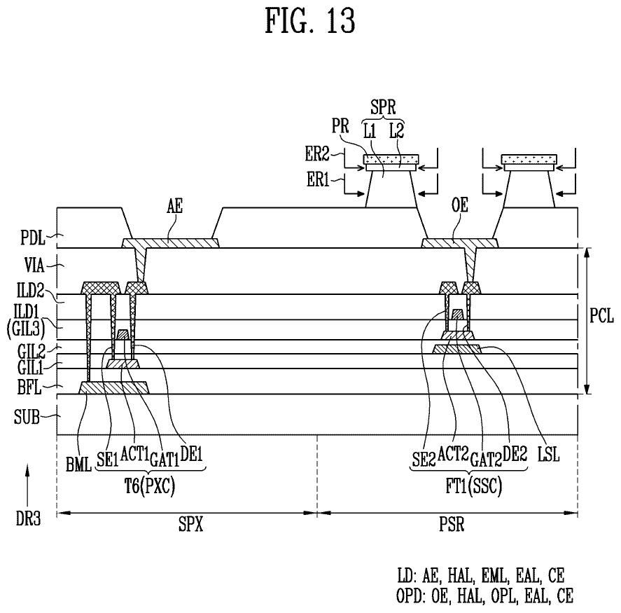

The first layer LI may include or be composed of a material with a first etch rate ER1 (see FIG. 13). In an embodiment, for example, the first layer L1 may include aluminum (Al), but embodiments are not necessarily limited to this. The second layer L2 may include or be made of a different material than the first layer L1. The second layer L2 may include or be composed of a material with a second etch rate ER2 (see FIG. 13), which is lower than the first etch rate ER1 (see FIG. 13). In an embodiment, for example, the second layer L2 may include titanium (Ti), but embodiments are not necessarily limited to this. Thus, the first layer L1 and the second layer L2 may include or be composed of materials with different etch rates to form the tapered shape of the first layer L1.

The hole auxiliary layer HAL may be positioned on the anode AE, the pixel defining layer PDL, and the sensor electrode OE. The hole auxiliary layer HAL may be provided in the second-first emission area EMA2−1, the light-receiving area LRA, and the non-emission area NEA, and may be partially discontinuous. In an embodiment, for example, the portion of the hole auxiliary layer HAL included in the sub-pixel SPX may be formed continuously, while the portion of the hole auxiliary layer HAL included in the light-sensing pixel PSR may be formed discontinuously. The hole auxiliary layer HAL may be interrupted or disconnected by separators SPR, and the interrupted portions of the hole auxiliary layer HAL may be positioned on the separators SPR. The hole auxiliary layer HAL may include a hole injection layer and/or a hole transport layer, but embodiments are not necessarily limited to these.

The emission layer EML may be positioned on the hole auxiliary layer HAL. The emission layer EML may be provided in the second-first emission area EMA2−1. The emission layer EML may include organic emissive materials, inorganic emissive materials, hybrid organic/inorganic emissive materials, quantum dots, and/or quantum rods, but embodiments are not necessarily limited to these.

The light-receiving layer OPL may be positioned on the hole auxiliary layer HAL. The light-receiving layer OPL may be provided in the light-receiving area LRA. The light-receiving layer OPL may include organic photosensitive materials such as dithiolene-based materials (BDN) (e.g., bis(4-dimethylaminodithiobenzil)nickel II), benzotriazole-based polymers (PTZBTTT-BDT), and/or porphyrin-based small molecule materials (DHTBTEZP), but embodiments are not necessarily limited to these.

The electron auxiliary layer EAL may be positioned on the emission layer EML, the light-receiving layer OPL, and the hole auxiliary layer HAL. The electron auxiliary layer EAL may be provided in the second-first emission area EMA2−1, the light-receiving area LRA, and the non-emission area NEA, and may be partially discontinuous or disconnected. In an embodiment, for example, the portion of the electron auxiliary layer EAL included in the sub-pixel SPX may be formed continuously, while the portion of the electron auxiliary layer EAL included in the light-sensing pixel PSR may be formed discontinuously. The electron auxiliary layer EAL may be interrupted by the separators SPR, and the interrupted portions of the electron auxiliary layer EAL may be positioned on the hole auxiliary layer HAL over the separators SPR. The electron auxiliary layer EAL may include an electron injection layer and/or an electron transport layer, but embodiments are not necessarily limited to these.

The cathode CE may be positioned on the electron auxiliary layer EAL. The cathode CE may be provided in the second-first emission area EMA2−1, the light-receiving area LRA, and the non-emission area NEA, and may be partially discontinuous. In an embodiment, for example, the portion of the cathode CE included in the sub-pixel SPX may be formed continuously, while the portion of the cathode CE included in the light-sensing pixel PSR may be formed discontinuously. The cathode CE may be interrupted by the separators SPR, and the interrupted portions of the cathode CE may be positioned on the electron auxiliary layer EAL over the separators SPR. The cathode CE may include metal layers such as silver (Ag), magnesium (Mg), aluminum (Al), platinum (Pt), palladium (Pd), gold (Au), nickel (Ni), neodymium (Nd), iridium (Ir), chromium (Cr), and/or transparent conductive layers such as indium tin oxide (ITO), indium zinc oxide (IZO), zinc oxide (ZnO), or indium tin zinc oxide (ITZO). The cathode CE may include or be composed of multiple layers including metal foil layers. For example, the cathode CE may include or be composed of a triple layer of ITO/Ag/ITO, although embodiments are not necessarily limited to these.

Parts of the anode AE provided in the second-first emission area EMA2−1, parts of the hole auxiliary layer HAL, the emission layer EML, parts of the electron auxiliary layer EAL, and parts of the cathode CE may constitute a light-emitting element LD. Holes injected from the anode AE through the hole auxiliary layer HAL and electrons injected from the cathode CE through the electron auxiliary layer EAL are transported into the emission layer EML to form excitons, and when the excitons transition from an excited state to the ground state, light may be generated. The brightness of the light may be determined by the current flowing through the emission layer EML. Depending on the composition of the emission layer EML, the wavelength range of the emitted light may be determined.

Portions of the sensing electrode OE provided in the light-receiving area LRA, portions of the hole auxiliary layer HAL, the light-receiving layer OPL, portions of the electron auxiliary layer EAL, and portions of the cathode CE may constitute a light-receiving element OPD. The light-receiving element OPD may function as an optical fingerprint sensor. In an embodiment, for example, the light-receiving element OPD may include or be composed of a photodiode, a complementary metal-oxide semiconductor (CMOS) image sensor, a charge-coupled device (CCD) camera, or a phototransistor, but embodiments are not necessarily limited to these. The light-receiving element OPD may sense light reflected by an external object (for example, a user's finger) to recognize a fingerprint. In an embodiment, for example, when a user's finger contacts the window WD (see FIG. 3), light emitted from the light-emitting element LD is reflected by the ridges or valleys of the finger, and the reflected light may reach the light-receiving element OPD. The light-receiving element OPD may distinguish between light reflected from the ridges and light reflected from the valleys of the finger, thereby enabling recognition of the user's fingerprint pattern.

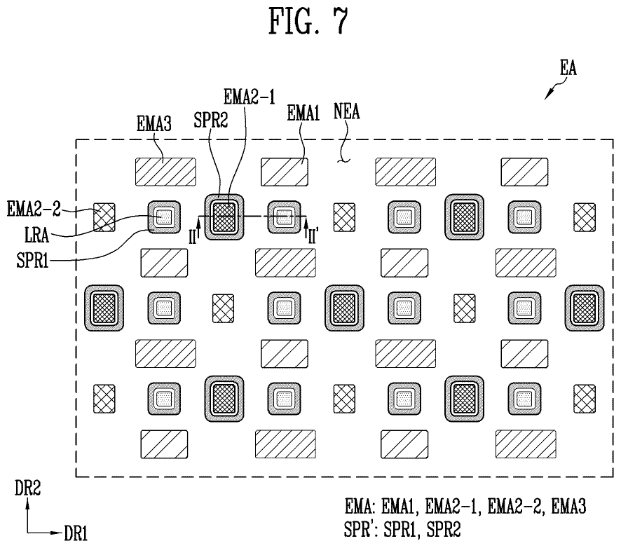

FIG. 7 is an enlarged view of the area EA of FIG. 2 according to another embodiment. With respect of FIG. 7, any repetitive detailed description of the same or like elements as those described above with reference to FIG. 5 will be omitted or simplified.

Referring to FIG. 7, separators SPR′ may be provided in the non-emission area NEA. The separators SPR′ may include first separators SPR1 and second separators SPR2.

Each of the first separators SPR1 may be positioned adjacent to each of the light-receiving areas LRA. In an embodiment, for example, each of the first separators SPRI may entirely surround each of the light-receiving areas LRA. However, embodiments are not necessarily limited to this. In another embodiment, for example, each of the first separators SPR1 may partially surround each of the light-receiving areas LRA. The first separators SPR1 may be substantially identical to the separators SPR shown in FIG. 5.

Each of the second separators SPR2 may be positioned adjacent to one of the emission areas EMA. In an embodiment, for example, each of the second separators SPR2 may be positioned adjacent to each of the second-first emission areas EMA2−1. Each of the second separators SPR2 may entirely surround each of the second-first emission areas EMA2−1. However, embodiments are not necessarily limited to this. In another embodiment, for example, each of the second separators SPR2 may partially surround each of the second-first emission areas EMA2−1.

In another embodiment, each of the second separators SPR2 may be positioned adjacent to each of the first emission areas EMA1, each of the second-second emission areas EMA2−2, or each of the third emission areas EMA3.

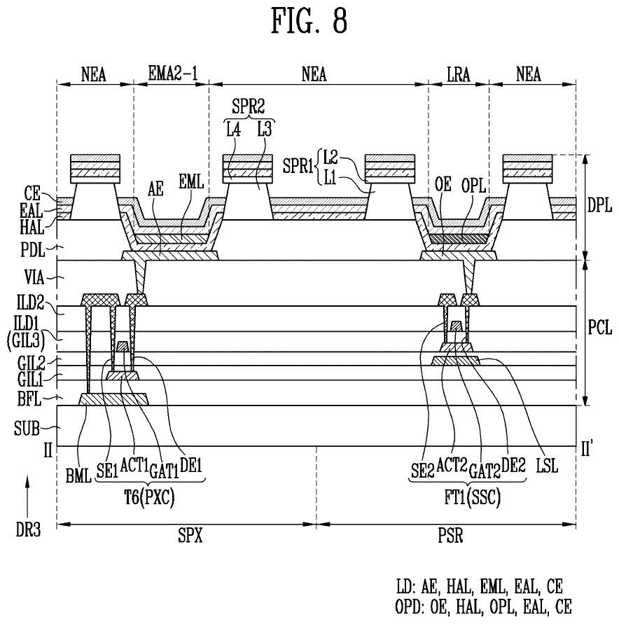

FIG. 8 is a cross-sectional view taken along line II-II′ of FIG. 7. With respect to FIG. 8, any repetitive detailed description of the same or like elements as those described above with reference to FIG. 6 will be brief or omitted. In FIG. 8, since the first separator SPR1 is substantially identical to the separator SPR shown in FIG. 6, any repetitive detailed description thereof will be omitted or simplified.

Referring to FIG. 8, the second separator SPR2 may be positioned on the pixel defining layer PDL. The second separator SPR2 may be provided in the non-emission area NEA and may be adjacent to the second-first emission area EMA2−1. The adjacency of the second separator SPR2 to the second-first emission area EMA2−1 may indicate that the second separator SPR2 is positioned closer to the second-first emission area EMA2−1 than to the light-receiving area LRA. Similar to the first separator SPR1, the second separator SPR2 may disrupt the hole auxiliary layer HAL, the electron auxiliary layer EAL, and the cathode CE provided in the non-emission area NEA adjacent to the second-first emission area EMA2−1. As a result, lateral leakage between the sub-pixels SPX and the light-sensing pixels PSR may be more effectively prevented or substantially reduced. Therefore, the operational reliability of the light-sensing pixels PSR may be further increased.

The second separator SPR2 may have a multi-layer structure. In an embodiment, for example, the second separator SPR2 may include a third layer L3 and a fourth layer L4 positioned on the third layer L3. In a cross-sectional view, the third layer L3 may have a tapered shape with a width which gradually decreases in the third direction DR3. In an embodiment, for example, the width of the bottom surface of the third layer L3 may be greater than the width of its top. In a cross-sectional view, the fourth layer L4 may have a rectangular shape, but embodiments are not necessarily limited to this. The width of the bottom surface of the fourth layer L4 may be greater than the width of the top surface of the third layer L3.

The third layer L3 may include or be composed of a material with a first etch rate ER1 (see FIG. 13). In an embodiment, for example, the third layer L3 may include aluminum (Al), but embodiments are not necessarily limited to this. The fourth layer L4 may include or be made of a different material than the third layer L3. The fourth layer L4 may include or be composed of a material with a second etch rate ER2 (see FIG. 13), which is lower than the first etch rate ER1. In an embodiment, for example, the fourth layer L4 may include titanium (Ti), but embodiments are not necessarily limited to this. Thus, the third layer L3 and the fourth layer L4 may include or be composed of materials with different etch rates to form the tapered shape of the third layer L3.

In such an embodiment, the third layer L3 of the second separator SPR2 may be substantially identical to the first layer L1 of the first separator SPR1. Additionally, the fourth layer L4 of the second separator SPR2 may be substantially identical to the second layer L2 of the first separator SPR1.

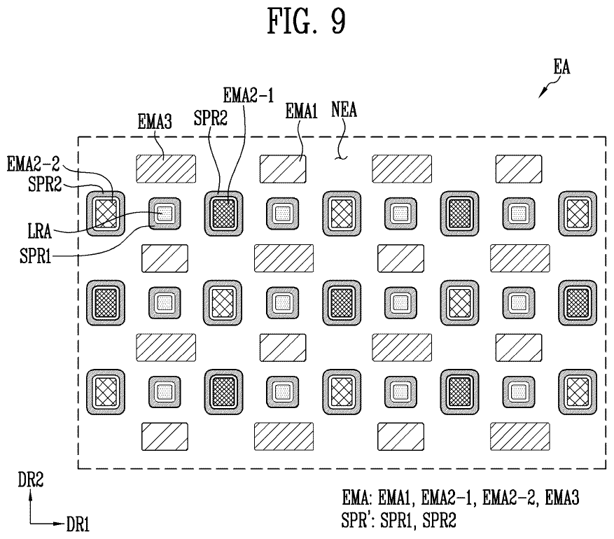

FIG. 9 is an enlarged view of the area EA of FIG. 2 according to one embodiment. With respect to FIG. 9, any repetitive detailed description of the same or like elements as those described above with reference to FIGS. 5 and 7 will be omitted or simplified.

Referring to FIG. 9, the second separators SPR2 may each be positioned adjacent to two of the emission areas EMA. In an embodiment, for example, the second separators SPR2 may each be positioned adjacent to the second-first emission areas EMA2−1 and the second-second emission areas EMA2−2. The second separators SPR2 may each entirely surround the second-first emission areas EMA2−1 and the second-second emission areas EMA2−2. However, embodiments are not necessarily limited to this. In another embodiment, for example, the second separators SPR2 may each partially surround the second-first emission areas EMA2−1 and the second-second emission areas EMA2−2.

In another embodiment, the second separators SPR2 may each also be positioned adjacent to any combination of the first emission areas EMA1 and the third emission areas EMA3, the first emission areas EMA1 and the second-first emission areas EMA2−1, the first emission areas EMA1 and the second-second emission areas EMA2−2, the third emission areas EMA3 and the second-first emission areas EMA2−1, or the third emission areas EMA3 and the second-second emission areas EMA2−2.

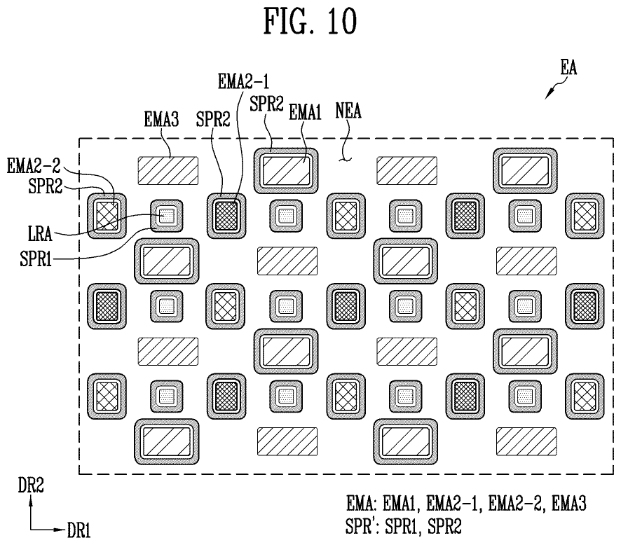

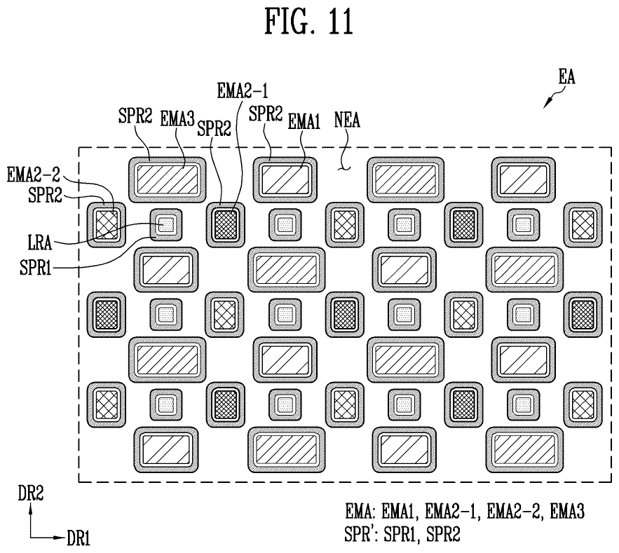

FIG. 10 is an enlarged view of the area EA of FIG. 2 according to one embodiment. With respect to FIG. 10, any repetitive detailed description of the same or like elements as those described above with reference to FIGS. 5 and 7 will be omitted or simplified.

Referring to FIG. 10, the second separators SPR2 may each be positioned adjacent to three of the emission areas EMA. In an embodiment, for example, the second separators SPR2 may be positioned adjacent to the first emission areas EMA1, the second-first emission areas EMA2−1, and the second-second emission areas EMA2−2. The second separators SPR2 may each entirely surround the first emission areas EMA1, the second-first emission areas EMA2−1, and the second-second emission areas EMA2−2. However, embodiments are not necessarily limited to this. In another embodiment, for example, the second separators SPR2 may each partially surround the first emission areas EMA1, the second-first emission areas EMA2−1, and the second-second emission areas EMA2−2.

In another embodiment, the second separators SPR2 may each also be positioned adjacent to the second-first emission areas EMA2−1, the second-second emission areas EMA2−2, and the third emission areas EMA3; the first emission areas EMA1, the second-second emission areas EMA2−2, and the third emission areas EMA3; or the first emission areas EMA1, the second-first emission areas EMA2−1, and the third emission areas EMA3.

FIG. 11 is an enlarged view of the area EA of FIG. 2 according to one embodiment. With respect to FIG. 11, any repetitive detailed description of the same or like elements as those described above with reference to FIGS. 5 and 7 will be omitted or simplified.

Referring to FIG. 11, the second separators SPR2 may be positioned adjacent to each of the emission areas EMA. In an embodiment, for example, the second separators SPR2 may each be positioned adjacent to the first emission areas EMA1, the second-first emission areas EMA2−1, the second-second emission areas EMA2−2, and the third emission areas EMA3. The second separators SPR2 may each entirely surround the first emission areas EMA1, the second-first emission areas EMA2−1, the second-second emission areas EMA2−2, and the third emission areas EMA3. However, embodiments are not necessarily limited to this. In another embodiment, for example, the second separators SPR2 may each partially surround the first emission areas EMA1, the second-first emission areas EMA2−1, the second-second emission areas EMA2−2, and the third emission areas EMA3.

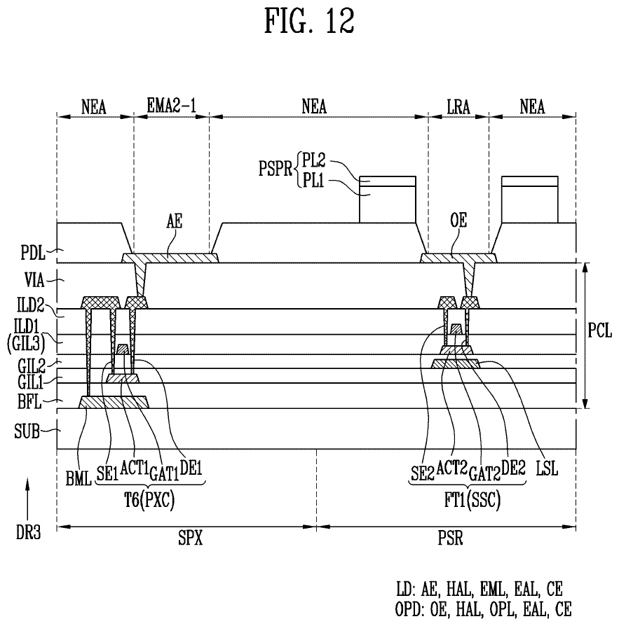

FIGS. 12 to 17 are cross-sectional views illustrating a method for manufacturing a display device according to an embodiment. In FIGS. 12 to 17, it will be understood that the substrate SUB, pixel circuit layer PCL, anode AE, sensor electrode OE, and pixel defining layer PDL are sequentially fabricated according to known processes.

Referring to FIG. 12, in an embodiment of a method for manufacturing a display device, a preliminary separator PSPR may be formed on the pixel defining layer PDL. The preliminary separator PSPR may be formed in the non-emission area NEA adjacent to the light-receiving area LRA. The preliminary separator PSPR may include a first preliminary layer PL1 and a second preliminary layer PL2 formed on the first preliminary layer PL1. The first preliminary layer PL1 may include or be formed of a material with a first etch rate ER1 (see FIG. 13), and the second preliminary layer PL2 may include or be formed of a material with a second etch rate ER2 (see FIG. 13), which is lower than the first etch rate ER1.

Referring to FIG. 13, after forming a photoresist PR on the preliminary separator PSPR (see FIG. 12), a separator SPR may be formed through an etching process. Since the first etch rate ER1 is higher than the second etch rate ER2, the first preliminary layer PL1 (see FIG. 12) may be etched deeper than the second preliminary layer PL2 (see FIG. 12). Utilizing this difference in etch rates, the first layer L1 with a tapered cross-sectional shape and the second layer L2 with a rectangular cross-sectional shape may be formed. After the etching process is completed, the photoresist PR may be removed.

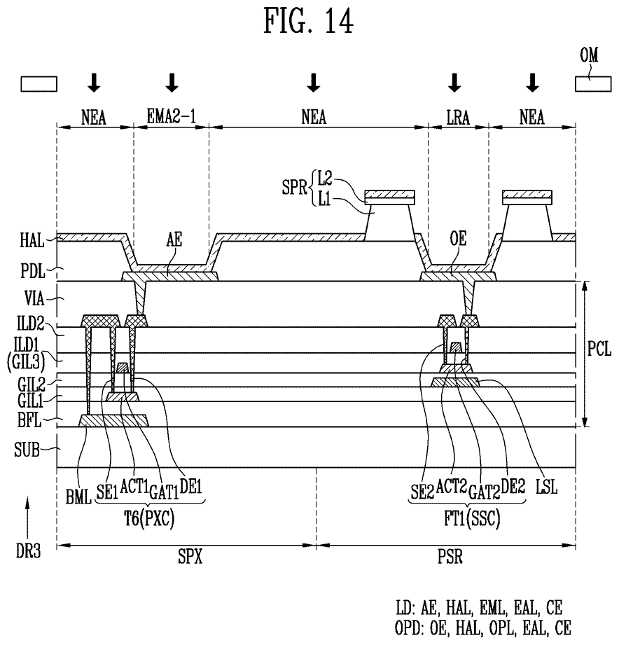

Referring to FIG. 14, using an open mask OM, the hole auxiliary layer HAL may be formed entirely over the second-first emission area EMA2−1, the light-receiving area LRA, and the non-emission area NEA. The hole auxiliary layer HAL may be formed discontinuously in the non-emission area NEA adjacent to the light-receiving area LRA due to the separator SPR. In an embodiment, for example, in the non-emission area NEA adjacent to the light-receiving area LRA, the hole auxiliary layer HAL may be formed on the pixel defining layer PDL and the separator SPR, with discontinuity.

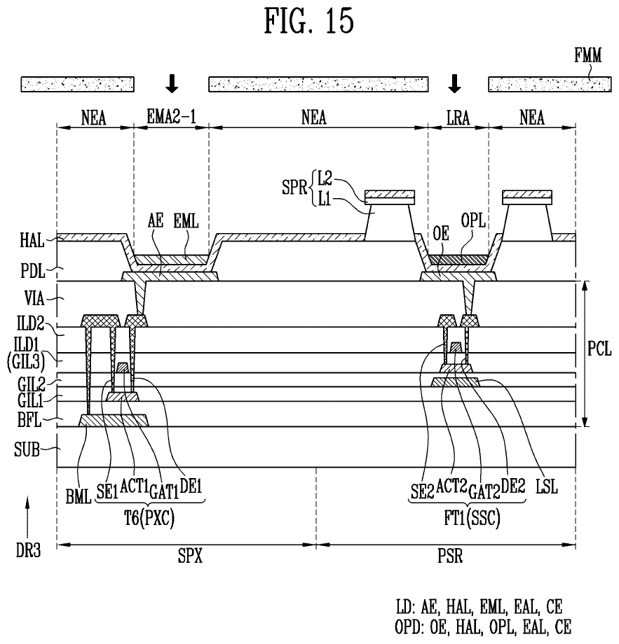

Referring to FIG. 15, using a fine metal mask FMM, the emission layer EML may be partially formed in the second-first emission area EMA2−1, and the light-receiving layer OPL may be partially formed in the light-receiving area LRA. The emission layer EML may be formed on a portion of the hole auxiliary layer HAL overlapping the second-first emission area EMA2−1, and the light-receiving layer OPL may be formed on a portion of the hole auxiliary layer HAL overlapping the light-receiving area LRA.

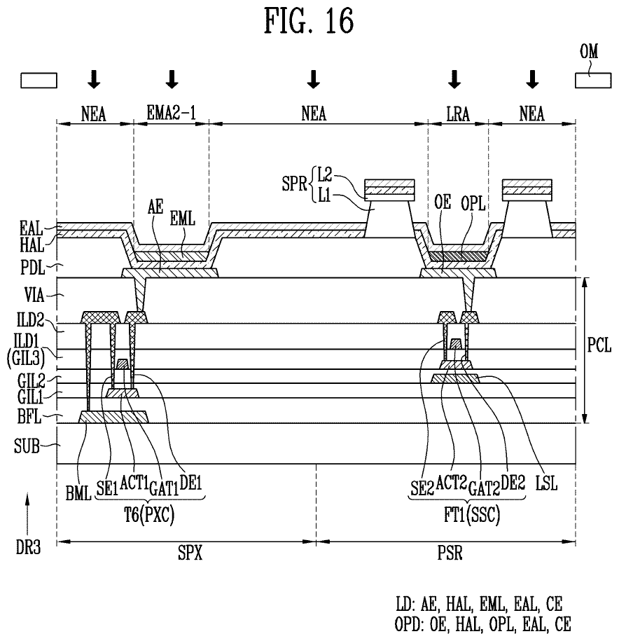

Referring to FIG. 16, using an open mask OM, the electron auxiliary layer EAL may be formed entirely over the second-first emission area EMA2−1, the light-receiving area LRA, and the non-emission area NEA. The electron auxiliary layer EAL may be formed discontinuously in the non-emission area NEA adjacent to the light-receiving area LRA due to the separator SPR. In an embodiment, for example, in the non-emission area NEA adjacent to the light-receiving area LRA, the electron auxiliary layer EAL may be formed on the hole auxiliary layer HAL and the separator SPR with discontinuity.

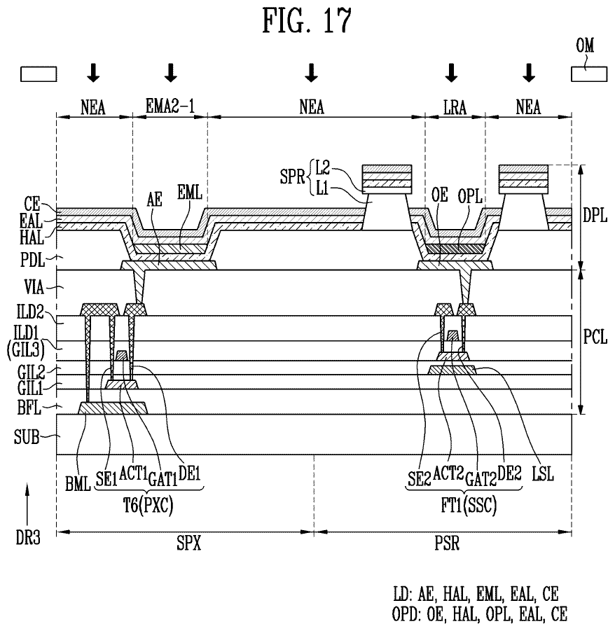

Referring to FIG. 17, using an open mask OM, the cathode CE may be formed entirely over the second-first emission area EMA2−1, the light-receiving area LRA, and the non-emission area NEA. The cathode CE may be formed discontinuously in the non-emission area NEA adjacent to the light-receiving area LRA due to the separator SPR. In an embodiment, for example, in the non-emission area NEA adjacent to the light-receiving area LRA, the cathode CE may be formed on the electron auxiliary layer EAL and the separator SPR with discontinuity.

In accordance with embodiments of the invention, lateral leakage between sub-pixels and light-sensing pixels may be effectively prevented (or substantially reduced), thereby increasing the sensing accuracy and reliability of the light-sensing pixels.

A display device according to an embodiment is applicable to various types of electronic devices. In an embodiment, an electronic device includes the above-described display device and may further include other modules or devices having additional functions in addition to the display device.

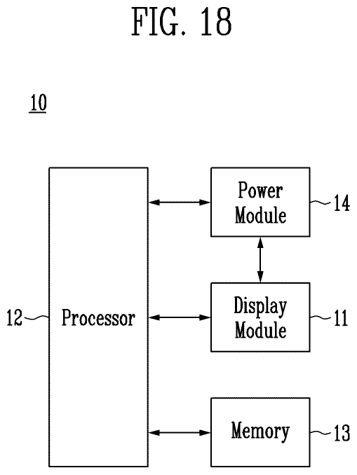

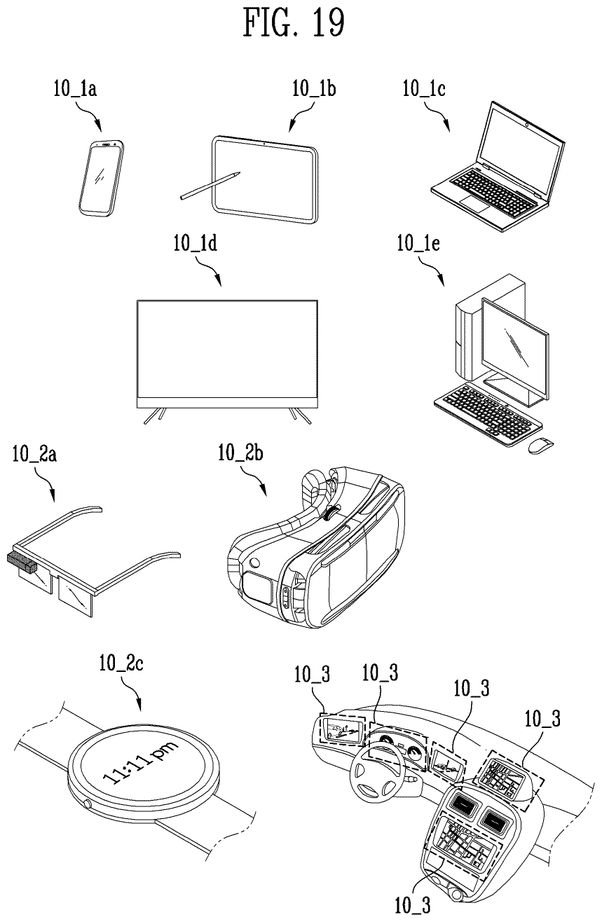

FIG. 18 is a block diagram of an electronic device according to an embodiment. Referring to FIG. 18, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

FIG. 19 shows schematic views of various embodiments of an electronic device.

Referring to FIG. 19, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display area; and
a sensing area overlapping at least a portion of the display area,
wherein the sensing area comprises:
an emission area;
a light-receiving area spaced apart from the emission area;
a non-emission area surrounding the emission area and the light-receiving area; and
a separator disposed in the non-emission area and positioned adjacent to the light-receiving area.

2. The display device of claim 1, wherein, in a plan view, the separator surrounds the light-receiving area.

3. The display device of claim 2, wherein the separator has a multilayer structure comprising a first layer and a second layer disposed on the first layer.

4. The display device of claim 3, wherein, in a cross-sectional view, the first layer has a tapered shape with a width which gradually decreases in a thickness direction, and the second layer has a rectangular shape.

5. The display device of claim 4, wherein, in the cross-sectional view, a width of a bottom surface of the second layer is greater than a width of a top surface of the first layer.

6. The display device of claim 1, wherein the sensing area further comprises:
a hole auxiliary layer overlapping the emission area, the light-receiving area, and the non-emission area, wherein the hole auxiliary layer is disconnected by the separator;
an emission layer disposed on a portion of the hole auxiliary layer overlapping the emission area;
a light-receiving layer disposed on a portion of the hole auxiliary layer overlapping the light-receiving area;
an electron auxiliary layer disposed on the hole auxiliary layer, the emission layer, and the light-receiving layer, wherein the electron auxiliary layer is disconnected by the separator; and
a cathode disposed on the electron auxiliary layer, wherein the cathode is disconnected by the separator.

7. A display device comprising:
a display area; and
a sensing area overlapping at least a portion of the display area,
wherein the sensing area comprises:
an emission area;
a light-receiving area spaced apart from the emission area;
a non-emission area surrounding the emission area and the light-receiving area;
a first separator positioned adjacent to the light-receiving area; and
a second separator positioned adjacent to the emission area.

8. The display device of claim 7, wherein, in a plan view, the first separator surrounds the light-receiving area and the second separator surrounds the emission area.

9. The display device of claim 8, wherein the first separator has a multilayer structure comprising a first layer and a second layer disposed on the first layer, and
wherein the second separator has a same multilayer structure as the first separator.

10. The display device of claim 9, wherein, in a cross-sectional view, the first layer has a tapered shape with a width which gradually decreases in a thickness direction, and the second layer has a rectangular shape.

11. The display device of claim 10, wherein, in the cross-sectional view, a width of a bottom surface of the second layer is greater than a width of a top surface of the first layer.

12. The display device of claim 7, wherein the sensing area further comprises:
a hole auxiliary layer overlapping the emission area, the light-receiving area, and the non-emission area, wherein the hole auxiliary layer is disconnected by the first separator and the second separator;
an emission layer disposed on a portion of the hole auxiliary layer overlapping the emission area;
a light-receiving layer disposed on a portion of the hole auxiliary layer overlapping the light-receiving area;
an electron auxiliary layer disposed on the hole auxiliary layer, the emission layer, and the light-receiving layer, wherein the electron auxiliary layer is disconnected by the first separator and the second separator; and
a cathode disposed on the electron auxiliary layer, wherein the cathode is disconnected by the first separator and the second separator.

13. An electronic device comprising:
a processor to provide input image data; and
a display device to display an image based on the input image data,
wherein the display device comprises:
a display area; and
a sensing area overlapping at least a portion of the display area, and
wherein the sensing area comprises:
an emission area;
a light-receiving area spaced apart from the emission area;
a non-emission area surrounding the emission area and the light-receiving area; and
a separator disposed in the non-emission area and positioned adjacent to the light-receiving area.

14. The electronic device of claim 13, wherein, in a plan view, the separator surrounds the light-receiving area.

15. The electronic device of claim 14, wherein the separator has a multilayer structure comprising a first layer and a second layer disposed on the first layer.

16. The electronic device of claim 15, wherein, in a cross-sectional view, the first layer has a tapered shape with a width which gradually decreases in a thickness direction, and the second layer has a rectangular shape.

17. The electronic device of claim 16, wherein, in the cross-sectional view, a width of a bottom surface of the second layer is greater than a width of a top surface of the first layer.

18. The electronic device of claim 13, wherein the sensing area further comprises:
a hole auxiliary layer overlapping the emission area, the light-receiving area, and the non-emission area, wherein the hole auxiliary layer is disconnected by the separator;
an emission layer disposed on a portion of the hole auxiliary layer overlapping the emission area;
a light-receiving layer disposed on a portion of the hole auxiliary layer overlapping the light-receiving area;
an electron auxiliary layer disposed on the hole auxiliary layer, the emission layer, and the light-receiving layer, wherein the electron auxiliary layer is disconnected by the separator; and
a cathode disposed on the electron auxiliary layer, wherein the cathode is disconnected by the separator.
